(19) United States
(12) Patent Application Publication
(10) Pub. No.: US 2007/0065964 A1
(43) Pub. Date: Mar. 22, 2007

(54) Integrated passive devices

(76) Inventor: Yinon Degani, Highland Park, NJ (US)

Correspondence Address: Law Firm of Peter V.D. Wilde, 301 East Landing, Williamsburg, VA, 23185, US

(21) Appl. No.: 11/232,550

(22) Filed: Sep. 22, 2005

(51) Int. Cl. H01L 21/00

(52) U.S. Cl. 438/48

(57) ABSTRACT

The specification describes a new composite IPD substrate material with properties that are compatible with highly integrated thin film structures. The new composite substrate is a laminate of a wafer of single crystal silicon and a wafer of an insulator. The composite is produced at the wafer level by bonding the silicon wafer and the insulating wafer together. This substantially reduces the time to process the substrate, and the cost. The insulator of the insulating wafer may be an organic or inorganic material with a resistivity greater than 500 ohm cm.

### FIELD OF THE INVENTION

This invention relates to integrated passive devices (IPDs) and more specifically to improved platforms for integrated passive device circuits.

### BACKGROUND OF THE INVENTION

(Portions of the technical material contained in this section may not be prior art.)

State of the art radio frequency (RF) electrical circuits use large quantities of passive devices. Many of these circuits are used in hand held wireless products. Accordingly, miniaturization of passive devices and passive device circuits is an important goal in RF device technology.

Integration and miniaturization of passive devices on the scale of active silicon devices has not occurred for at least two reasons. One, typical passive devices to date employ different material technologies. But, more fundamentally, the size of many passive devices is a function of the frequency of the device, and thus is inherently relatively large. However, still, there is unrelenting pressure to produce more compact and area-efficient IPDs.

Significant advances have been achieved. In may cases these involve surface mount technology (SMT). Small substrates containing large numbers of passive components are routinely produced using surface mount technology.

More recent advances in producing integrated passive device networks involve thin film technology where resistors capacitors and inductors are built as integrated thin film devices on a suitable substrate. See for example U.S. Pat. No. 6,388,290. This advance shows promise as the next generation of integration in passive device technology. However, just as the substrate material and character (pure single crystal silicon) have been key to the success in active device technology, it is becoming evident that the same is true as IPD integration develops. Because passive thin film devices are formed directly on the substrate, electrical interactions between the substrate and the passive devices are of major concern. And although suitable thin film technologies for producing the passive components are available, the ideal substrate for this technology has yet to be found.

One promising approach is described in patent application Ser. No. 10/835,338 filed in the United States on Apr. 29, 2004, assigned to a common assignee, the contents of which are incorporated by reference herein. That approach uses polysilicon as the IPD substrate material.

### SUMMARY OF THE INVENTION

We have developed a new composite IPD substrate material with properties that are compatible with highly integrated thin film structures. The new composite substrate is a laminate of a wafer of single crystal silicon and a layer of an insulator. The composite is produced at the wafer level by bonding the silicon wafer and the insulating layer together. This substantially reduces the time to process the substrate, and the cost. The insulator of the insulating layer may be an organic or inorganic material with a resistivity greater than 500 ohm cm.

The use of single crystal silicon as a primary substrate material is ubiquitous in IC technology. However, the resistivity of silicon is too low to serve as a primary IPD substrate material. Consequently, the common practice would be to substitute an insulating substrate such as alumina for an IPD substrate. An alternative might be to use silicon on which an insulating SiO₂ layer is grown. However, this requires substantial processing to obtain layers thick enough for an IPD application. Another option would be to deposit an insulating layer on the silicon substrate. Again, to obtain a layer of substantial thickness may require processing that is excessive in terms of cost.

### BRIEF DESCRIPTION OF THE DRAWING

FIG. 1 shows a starting wafer of single crystal silicon and an insulating layer or wafer;

FIG. 2 shows the two elements of FIG. 1 bonded together;

FIG. 3 is a view of the composite wafer of the invention showing over 500 IPD sites for building thin film IPDs;

FIG. 4 is a schematic section view of a typical IPD showing conventional SMT components mounted on a conventional substrate;

FIG. 5 is a cross section view of a thin film approach to IPD fabrication on one of the sites of the substrate of FIG. 3;

FIG. 6 is a schematic circuit diagram showing an example of an IPD;

FIG. 7 shows the IPD with an active IC chip mounted on the IPD.

### DETAILED DESCRIPTION

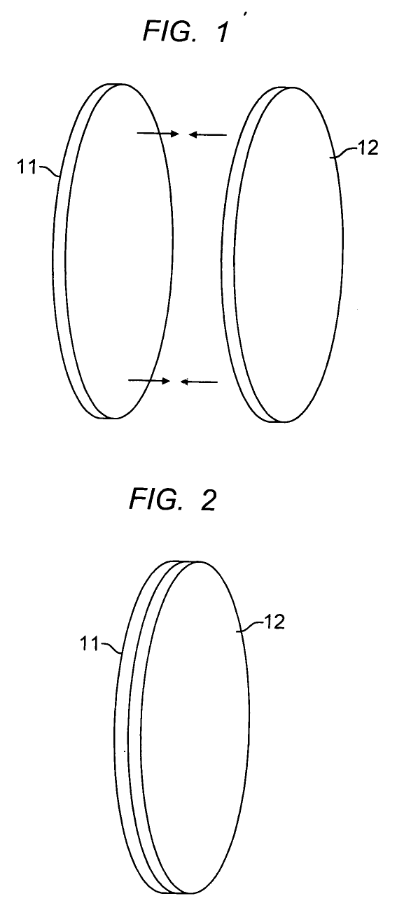

FIG. 1 is a view of the starting elements. Element 11 is a single crystal silicon waver wafer typically cut from a boule, and is of a type of wafer used in enormous volume for IC device fabrication worldwide. Silicon wafers are produced in many sizes, but typically the larger the diameter of the wafer, the lower the potential device cost. Currently, silicon wafers are available in diameters up to twelve inches. With twelve-inch wafers state of the art, that size will be used as the example in the following description, it being understood that smaller wafers, for example 6″ or 8″, are also useful.

In a wafer production facility, after sawing and polishing the wafers, each wafer is subjected to quality control, where the wafer is measured for conformity to rigid standards for physical size and electrical properties. Typically wafers with chips or scratches will be rejected. Wafers that have excessive or non-uniform conductivity are also rejected. In many cases the rejected wafers are scrapped, and sometimes referred to as “junk wafers”. In this description, and in the claims that follow, a “refuse” wafer includes wafers that are cut from a boule, measured by one or more physical or electrical tests, and rejected for failing a test. Refuse wafers have relatively low commercial value. Some may be recycled. Some may be repaired. For example, some wafers are rejected for defects that occur during processing. These wafers have the potential to be polished to remove the defective structure, and used for processing. Such wafers are also defined as refuse wafers. A refuse wafer may be expected to have a value of less than 50%, and more typically, less than 10%, of the value of an acceptable wafer.

According to the invention, a single crystal silicon wafer is used as the main physical component of the IPD substrate. It should be understood that while a refuse wafer may be the wafer of choice for economic reasons, any suitable single crystal silicon wafer may be used. Typically the silicon wafer is thin, e.g. 200-700 microns. However, it is sufficiently thick to be relatively robust physically, and can be handled and processed. It is very flat over a large area and has a highly polished, uniformly smooth, surface. And it is compatible with silicon wafer fabrication processes and tools.

Resistivity of the silicon wafer, normally a relevant parameter in conventional IC processing, is not relevant in this IPD fabrication method. That allows an additional category of refuse wafers, i.e. wafers that don't meet strict resistivity criteria, to be used, adding to the cost benefit of the method.

Using the silicon wafer as the primary physical support for the IPD substrate, an insulating material is applied to the top surface of the silicon substrate. The insulating layer or wafer, shown at 12 in FIG. 1, is bonded to the surface of the silicon wafer as indicated schematically in FIG. 1. The bonded and completed substrate is shown in FIG. 2. The insulating material of layer 12 may be organic or inorganic. If it is an organic insulator, such as polyimide or teflon, it may be applied to the silicon substrate as a thin flexible film, to form the insulating layer. If it is an inorganic material, such as alumina, titania, zirconia, silica glass, it will typically be in the form of a very thin wafer or sheet. While the insulating material appears in FIG. 1 as resembling a wafer, it may be a sheet with any shape as long as it substantially covers the surface of silicon wafer 11.

The insulating layer should be relatively thick, for example at least 25 microns, and preferably at least 100 microns. Minimum thickness will depend in part on the resistivity. A suitable resistivity is at least 500, and preferably at least 1000, ohm cm. The top of the thickness range is dictated mostly by strength considerations, and the size of the completed package. In general, little benefit will accrue for a thickness above 300 microns. Organic layers in this thickness range offer the advantage that they are pliable, and usually elastic. This avoids the stresses sometimes found in composite structures of inorganic material. The material of the insulating layer should be capable of withstanding whatever processing temperatures that are occur later in the IPD assembly process. These may be as high or higher than 400° C.

A variety of bonding methods may be used. The bonding method, per se, forms is not part of the invention. If a polymer sheet is used as layer 12, bonding may be by a thermal or thermocompression process. Adhesive bonding is also useful. In some cases it may be helpful to pre-oxidize the silicon wafer to enhance adhesion of layer 12. If layer 12 is an inorganic material, an adhesive polymer coating or film may be sandwiched between layers 11 and 12 to bond them together.

The composite wafer substrate shown in FIG. 2 is relatively robust, sufficiently so that it will withstand at least some or all of the processing steps required for completing the IPD. The processed wafer may then be thinned in a later step to remove at least part of the silicon layer.

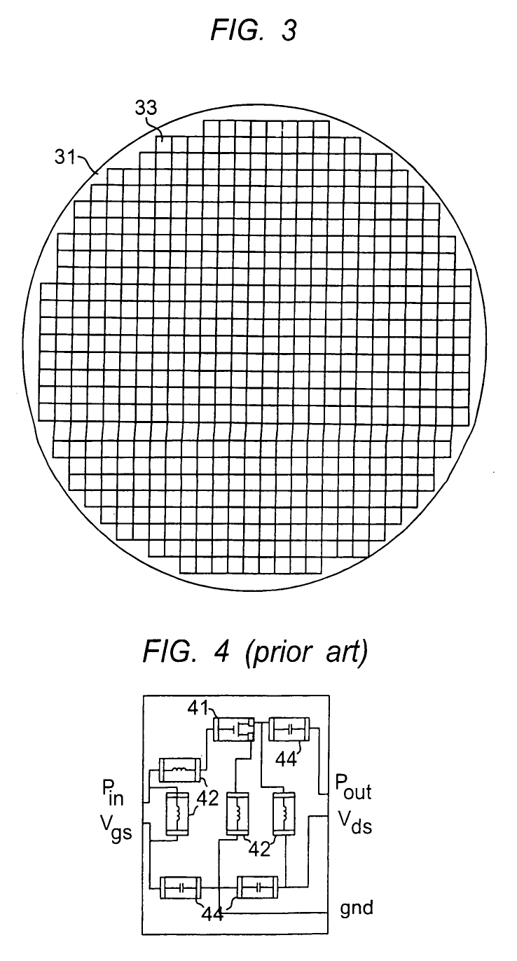

The IPD production approach described here is aimed at wafer scale device fabrication. In this approach, a large number of finished, or nearly finished, devices are produced on the composite wafer. After fabrication is essentially complete, the wafer is diced into IPD devices. As the size of wafers increases, and IPD device size shrinks, wafer level fabrication becomes ever more attractive. FIG. 3 shows a twelve inch wafer 31, which is capable of providing more than 500 device sites 33. (For simplicity, the wafer flat is not shown.) Each site is approximately a centimeter square, easily large enough to accommodate an IPD.

The effectiveness of wafer scale fabrication can be multiplied using thin film fabrication approaches for forming the passive devices. A common prior art approach, even at the wafer level, is to mount and attach discrete passive elements to the wafer substrate. Typically this is done using surface mount technology (SMT). FIG. 4 shows this method as applied to the IPD circuit illustrated in FIG. 3 of U.S. Pat. No. 6,388,290, referenced earlier. This circuit is not strictly an IPD because it contains an active element, i.e. MOS transistor 41. However, for reasons that will become apparent below, it is a useful illustration. The circuit may be considered a hybrid circuit having an active portion and a passive portion. The concern here is mainly with the passive portion, i.e. the portion that contains four inductors 42 and three capacitors 44. As a matter of choice, that portion could be produced as an IPD. Although the circuit of FIG. 4 is useful here, and below, as a vehicle to illustrate the technology of the invention, a wide variety of circuits may be made using the invention. For another example, and one that may be more demanding from a high-Q standpoint, see Proceedings 1994 IEEE MULTI-CHIP MODULE CONFERENCE MCMC-94, PAGES 15-19, incorporated herein by reference.

Thin film passive elements may be formed by a variety of thin film techniques. These techniques are well developed and the specifics need not be reiterated here. See for example U.S. Pat. No. 6,075,691, issued Jun. 13, 2000, and U.S. Pat. No. 6,005,197, issued Dec. 21, 1999, both incorporated here by reference. The latter patent describes a multi-layer structure for PCBs, which could easily be adapted for the application described here. A convenient way of defining a thin film passive device is a passive device that is formed on a substrate using one or more layers, typically a plurality of layers, deposited on the substrate.

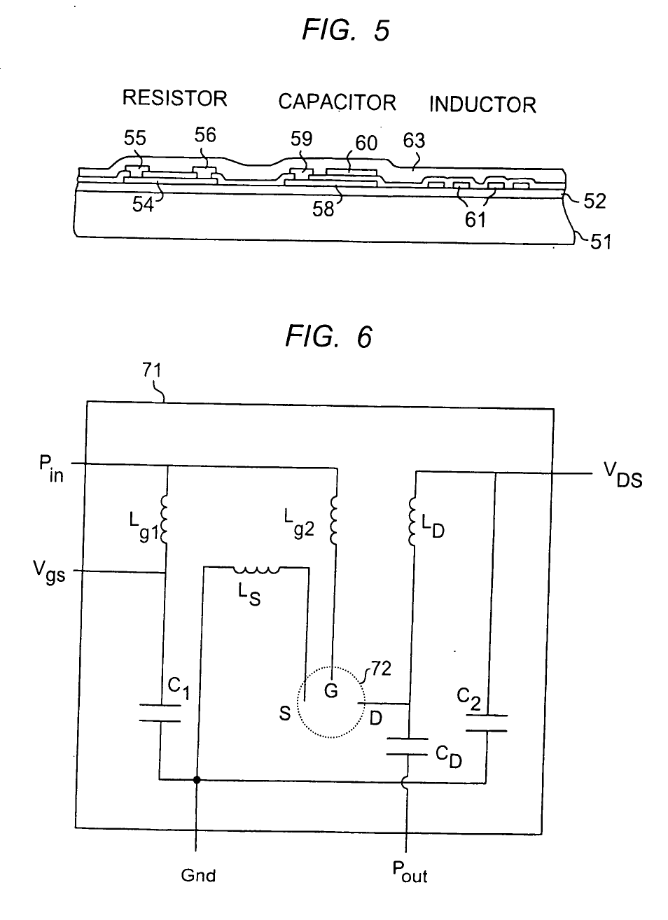

Thin film methods for producing combinations of at least two interconnected passive elements (an IPD) are generically represented by FIG. 5, wherein the silicon substrate is shown at 51, with insulating layer 52 bonded to the surface of the silicon substrate. The cutaway portion shown in FIG. 5 is a smaller portion of an IPD chip (or wafer). Resistor body 54, formed from first level metal, has contacts 55 and 56, and lower capacitor plate 58, with contact 59, both comprise buried levels. Upper capacitor plate 60, and inductor spiral 61, are formed last, with contacts not shown. The structure is protected with polyimide layer 63.

The composite substrate structure of FIG. 5 is relatively thick, which reduces the risk of fracture and other damage during processing. After fabrication of the passive circuit elements, and completion of the IPD, the substrate 51 may be thinned, for example from 600 microns to 150 microns. The substrate may be thinned using chemical mechanical polishing (CMP). This well known process combines abrasive polishing with chemical etching. KOH or a suitable alternative etchant is used in the abrasive slurry. The thickness of the finished IPD substrate is preferably 100-500 microns. If the thickness of the insulating layer is sufficient for mechanical integrity, the entire silicon substrate wafer may be removed.

The IPD of FIG. 4 is shown implemented according to the invention in FIG. 6. The IPD is formed on one or more of the sites 33 shown in FIG. 3. A composite insulating substrate, like that of FIG. 2 is shown at 71. The substrate is shown with thin film inductors L_{g1}, L_{g2}, L_{S} and L_{D}, and capacitors C₁, C₂, and C_{D}. MOS transistor 72 is shown in phantom because, while part of the schematic circuit, it is not formed in the IPD. The circuit layout for FIG. 6 is deliberately changed from that of FIG. 3. This circuit and this layout are for the purpose of illustrating a typical type of circuit having passive components. It is an example of a circuit taken from the prior art referenced earlier. No representation as to its effectiveness is made here.

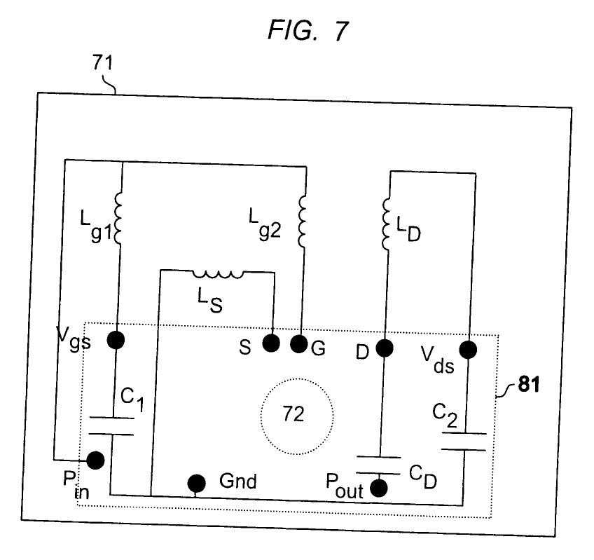

The layout in FIG. 6 is designed with all the inductor elements grouped together. It is known that inductor elements are especially sensitive to ambient conditions, e.g. parasitic signals. This recognition is employed in the design of the active/passive module shown in FIG. 7. The polysilicon substrate 71, with the IPD shown in FIG. 6, has an active IC chip 81 flip-chip mounted over the top of the IPD as shown. Part of the active IC chip is transistor 72. The interconnections in this embodiment are shown as solder bumps for the electrical interconnections S, D, G, V_{gs}, V_{DS}, Pᵢₙ, Pₒᵤₜ, gnd. Off board interconnection sites (not shown) may be provided on the IPD substrate 71. One purpose of the grouping of the inductor devices as shown in FIG. 6 is evident in FIG. 7. The active IC chip is deliberately positioned so as not to overlay the sensitive inductor elements. Thus the stacked substrate arrangement is effectively implemented to save space and provide a compact device module, without compromising the performance of the inductor elements.

Various additional modifications of this invention will occur to those skilled in the art. All deviations from the specific teachings of this specification that basically rely on the principles and their equivalents through which the art has been advanced are properly considered within the scope of the invention as described and claimed.

1. A method for fabricating an integrated passive device (IPD) comprising the steps of:
(a) providing a single crystal silicon wafer substrate, the single crystal silicon wafer substrate having a plurality of IPD sites,
(b) bonding an insulating layer to the single crystal silicon wafer substrate, and
(c) forming at least two thin film passive devices on the IPD sites.

2. The method of claim 1 wherein the single crystal silicon wafer substrate has a thickness of at least 200 microns.

3. The method of claim 1 wherein the insulating layer has a thickness of at least 25 microns.

4. The method of claim 1 wherein the insulating layer comprises an organic material.

5. The method of claim 4 wherein the insulating layer is polyimide or teflon.

6. The method of claim 1 wherein the insulating layer comprises an inorganic material.

7. The method of claim 6 wherein the insulating layer comprises an material selected from the group consisting of alumina, titania, zirconia, and silica glasses.

8. The method of claim 1 comprising the additional step, after step c., of thinning the silicon wafer.

9. The method of claim 8 wherein the step of thinning the silicon wafer removes the silicon wafer.

10. The method of claim 8 comprising the additional step, after thinning the silicon wafer, of dicing the wafer into IPD chips.

11. The method of claim 1 wherein the single crystal silicon wafer is a refuse wafer.

12. The method of claim 1 wherein the single crystal silicon wafer and the insulating layer are bonded using an adhesive.

13. The method of claim 1 wherein the single crystal silicon wafer and the insulating layer are bonded using a thermal, thermocompression, or adhesive bonding method.

14. The method of claim 1 wherein the single crystal silicon wafer has a diameter of at least 8 inches.

15. An integrated passive device (IPD) comprising:
(a) a single crystal silicon wafer substrate, the single crystal silicon wafer substrate having a plurality of IPD sites,
(b) an insulating layer bonded to the single crystal silicon wafer substrate, and
(c) at least two thin film passive devices formed on the IPD sites.

16. The integrated passive device of claim 15 wherein the single crystal silicon wafer substrate has a thickness of at least 50 microns.

17. The integrated passive device of claim 15 wherein the insulating layer has a thickness of at least 50 microns.

18. The integrated passive device of claim 15 wherein the insulating layer comprises an organic material.

19. The integrated passive device of claim 15 wherein the insulating layer comprises an organic material selected from the group consisting of polyimide, teflon. or an inorganic material selected from the group consisting of alumina, titania, zirconia, and silica glasses.

20. An electrical device system comprising at least one IPD as claimed in claim 15.
